(19) United States
(12) Patent Application Publication
(10) Pub. No.: US 2009/0045503 A1
(43) Pub. Date: Feb. 19, 2009

(54) Multidirectional Semiconductor Device Package Thermal Enhancement Systems and Methods

(76) Inventor: Sreenivasan K. Koduri, Allen, TX (US)

Correspondence Address: TEXAS INSTRUMENTS INCORPORATED, P O BOX 655474, M/S 3999, DALLAS, TX, 75265, US

(21) Appl. No.: 11/840,604

(22) Filed: Aug. 17, 2007

(51) Int. Cl. H01L 23/48; H01L 21/00

(52) U.S. Cl. 257/693; 438/122; 257/E23.01

(57) ABSTRACT

The invention provides thermally-enhanced semiconductor device package systems and associated methods for reducing thermal resistance for improved heat egress. In one disclosed embodiment of the invention, a semiconductor device package system includes a packaged semiconductor device having operable contacts for external electrical coupling. The packaged device has an exposed surface, and a heat spreader is affixed to the exposed device surface. The heat spreader includes a portion extending in a configuration coplanar with the device contacts. In another example of a preferred embodiment of the invention, a semiconductor device package system includes an external heat sink affixed to a heat spreader, the heat spreader having a portion extending in a configuration coplanar with the device contacts. According to exemplary systems and methods of the invention package systems are provided with a heat spreader so configured that the junction-to-board thermal resistance and junction-to-case thermal resistance are both reduced.

### TECHNICAL FIELD

The invention relates to electronic semiconductor devices and manufacturing methods. More particularly, the invention relates to packaged microelectronic semiconductor assemblies having features for promoting heat egress from a packaged device and to methods for the manufacture of the same.

### BACKGROUND OF THE INVENTION

In conventional semiconductor device packages, a semiconductor device is mounted on a substrate, such as a metallic leadframe, with metallic connections and/or an adhesive material. Bond wires or contact pads on the device are coupled with leads or contact pads incorporated into the surface of the substrate. An encapsulant material forms a protective covering over the device, bond wires, and some or all of the substrate. In general, the semiconductor device within a package generates heat when operated and cools when inactive. Due to the changes in temperature, the package as a whole tends to thermally expand and contract. However, in many cases the thermal expansion behavior of the package, its internal components, e.g., device, leadframe, and underlying substrate such as a printed circuit board (PCB), can differ, causing stresses to occur at the connecting surfaces, or within the layers of the package, or among the layers of the device itself.

For these and perhaps other reasons, managing heat egress in microelectronic semiconductor device packages is a concern of practitioners of the art. As circuit densities increase and process geometries and form factors shrink, the amount of heat generated in a packaged device creates significant heat dissipation challenges. The heat necessarily dissipates from the device to its immediate surrounding environment, e.g., the surrounding package, and further to nearby structures. It is important to promote the efficient egress of heat from the device, otherwise the reliability of the device may be diminished. Typically, a packaged device is thermally isolated in all lateral directions by surrounding mold compound, which generally has poor heat conduction properties. The thermal paths through the “bottom” and “top” surfaces of the device are usually the most beneficial.

Package thermal resistance is the measure of the package's heat dissipation capability from a device's active surface (junction) to a specified reference point (case, board, ambient air, etc.). Thermal relationships for IC packages are commonly expressed in terms of the junction-to-air thermal resistance (θJA), junction-to-case thermal resistance (θJC), and junction-to-board thermal resistance (θJB). Junction-to-air thermal resistance (θJA) measures the heat flow from the device to the surrounding air via all paths, e.g., JC and JB.

Efforts known in the art to enhance heat flow from a packaged device tend to orient the device within the package in order to increase efficiency in either the junction-to-case direction, usually “bottom up”, or in the junction-to-board direction, usually “bottom down”. Such efforts generally are either detrimental to, or irrelevant to, the efficiency of the thermal path in the opposite direction. An exposed device surface or die pad in contact with the underlying substrate improves junction-to-board thermal resistance (θJB). On the other hand, an exposed device surface or die pad on the top of the package may be used to improve direct junction-to-air heat transfer. Also, an exposed device surface or die pad on the top of the package used in conjunction with an external heat sink may also be used to improve junction-to-case thermal resistance (θJC). It is also known to further enhance the dissipation of heat directly into the air with the addition of an external heat sink attached to the top of the package. In the packages known in the arts, it is possible that θJC or θJB may alternatively be either very low or very high, depending on the up or down configuration. For improved thermal performance of packaged devices, particularly wherein a large quantity of heat is produced, it would be useful and advantageous to provide simultaneous reductions of both junction-to-case thermal resistance (θJC), and junction-to-board thermal resistance (θJB).

In addition to the problems identified above, thermal enhancements known in the arts for IC packages are faced with the additional problem of tending to increase the cost of the overall package. In general, to the extent the standard package assembly process is disrupted, process efficiency and yields decrease, and costs increase. Due to these and other problems, it would be useful and advantageous to provide semiconductor packages, particularly relatively small packages such as for example QFN and other high-density flip-chip packages, with improved paths for the egress of heat, and to provide manufacturing methods for the same. The present invention is directed to overcoming, or at least reducing the effects of one or more of the problems noted.

### SUMMARY OF THE INVENTION

In carrying out the principles of the present invention, in accordance with preferred embodiments thereof, the invention provides thermally-enhanced semiconductor device package systems with reduced thermal resistance for improved heat egress.

According to one aspect of the invention, a semiconductor device package system includes a packaged semiconductor device having operable contacts for external electrical coupling. The packaged device has an exposed surface, and a heat spreader is affixed to the exposed device surface. The heat spreader includes a portion extending in a configuration coplanar with the device contacts.

According to another aspect of the invention, in an example of a preferred embodiment, a semiconductor device package system includes an external heat sink affixed to the heat spreader, the heat spreader having a portion extending in a configuration coplanar with the device contacts.

According to yet another aspect of the invention, a semiconductor device package system with a heat spreader having a portion extending in a configuration coplanar with the device contacts also includes an interlocking joint coupling the heat spreader and the packaged device.

According to still another aspect of the invention, a semiconductor device package system according to a preferred embodiment of the invention a heat spreader encircles the packaged device.

According to yet another aspect of the invention, a method for assembling a semiconductor device package system includes the step of providing a packaged semiconductor device having operable contacts for external electrical coupling with a substrate. The device also has an exposed surface, and in further steps a heat spreader is affixed to the exposed device surface. The heat spreader is provided with at least one extended portion coplanar with the device contacts for contacting the substrate.

According to another aspect of the invention, exemplary systems and methods of the invention provide a package system with a heat spreader so configured that the junction-to-board thermal resistance and junction-to-case thermal resistance are both reduced.

The invention has advantages including but not limited to one or more of the following, improved junction-to-air thermal resistance (θJA), improved junction-to-case thermal resistance (θJC), improved junction-to-board thermal resistance (θJB), increased reliability, and reduced costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of a package system according to the invention;

FIG. 2 is a cutaway side view of a further example of a preferred embodiment of a package system according to the invention;

FIG. 3 is a cutaway side view of an example of an alternative preferred embodiment of a package system according to the invention;

FIG. 4 is a top perspective view showing another example of preferred embodiments of package systems of the invention;

FIG. 5 is a top view of an example of a DIP package system in a preferred embodiment of the invention;

FIG. 6 is a section view of the exemplary embodiment of the invention according to FIG. 5 cut away at line 6-6;

FIG. 7 is a section view of the exemplary embodiment of the invention according to FIG. 5 cut away at line 7-7;

FIG. 8 is a top view of an example of a DIP package system in an alternative preferred embodiment of the invention;

FIG. 9 is section view of the exemplary embodiment of the invention according to FIG. 8 cut away at line 9-9; and

FIG. 10 is a section view of the exemplary embodiment of the invention according to FIG. 8 cut away at line 10-10.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

The invention provides thermal performance-enhanced semiconductor package systems and methods related to their manufacture. The invention takes a coordinated approach toward improving heat egress from a packaged semiconductor device through three major paths: from the top of the device, either directly or through the package, to the ambient air; from the bottom of the package to an underlying substrate, usually a PCB, and then to the air; and from the device leads to the substrate, and ultimately to the air. Many characteristics of the device, leads, package, and underlying substrate can influence the efficiency of heat flow through these paths, and a problem prevalent in the prior art is that improvement to one of these paths may be made at the expense of one or more of the other paths. Preferred embodiments of the invention reduce junction-to-air thermal resistance (θJA) by reducing both junction-to-case thermal resistance (θJC) and junction-to-board thermal resistance (θJB). The invention may be used to advantage in the context of PowerPad, QFN (quad flat no-lead), DIP (dual in-line), flip-chip, and other types of packages.

The “top” of a package is typically a relatively poor heat path due to inherent heat resistance of the encapsulant material covering the device. It is known in the arts to attempt to improve this thermal path by the addition of an external heat sink to the top of the outside of the package. Although sometimes helpful, this approach is necessarily limited by the inefficient heat transfer characteristics of the intervening mold compound. It is known to modify a package to make it amenable to the addition of the external heat sink by positioning the device so that it has an exposed surface, die pad, or heat spreader at the top of the package for receiving the heat sink. A problem with this approach is that only a portion of the heat energy is convected and radiated off the top surface of the package, i.e., through the heat sink. Often a significant portion of the thermal energy generated by the device in such a package is conducted to the PCB to which the package is attached. This thermal path from the “bottom” of the device is often the most direct. Enlarged die pads, thermal vias, or added heat slugs are sometimes incorporated into packages between the device and the board to decrease junction-to-board thermal resistance (θJB). The inclusion of a built-in heat slug component increases the cost of the package, as the integration of an additional internal component increases package complexity, adds assembly steps, and influences reliability and longevity. It has been determined that in some instances efforts made to configure the components of a package to decrease junction-to-case thermal resistance (θJC) results in an increase in junction-to-board thermal resistance (θJB), and vice versa. The present invention includes concurrent improvements in junction-to-case thermal resistance (θJC) and junction-to-board thermal resistance (θJB).

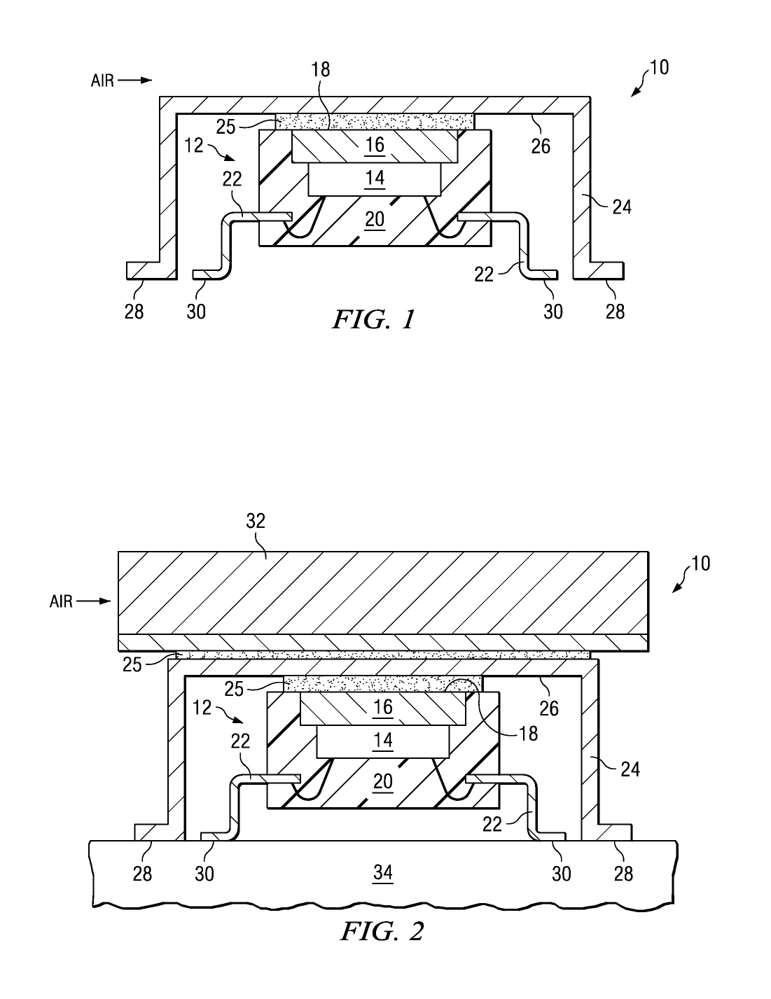

Referring primarily to FIG. 1, an example of a preferred embodiment of a package system 10 according to the principles of the invention is shown. A package 12 includes an operable semiconductor device 14, in this example, mounted on a die pad 16 having a surface 18 exposed at the top of the encapsulant 20 surrounding the device 14. Metallic leads 22 provide electrical connections between the device 14 and the world at large (not shown), as is known in the arts. The invention may also be practiced with leadless packages, as further described herein. A heat spreader 24 is preferably attached to the package 12 using suitable adhesive or thermal compound 25. The heat spreader 24 is preferably made from material selected for its heat conduction properties, such as metal, and includes a surface 26 configured for maximizing contact with the package 12, in this example with the exposed die pad surface 18. The heat spreader 24 also preferably includes an extended portion 28 coplanar with the external ends 30 of the electrical contacts, in this case leads 22, coupled to the device 14. Heat dissipation is provided through conduction from the device 14, to the die pad 16, to the heat spreader 24, and then further to the surrounding air by convection. Additionally, heat may preferably be conducted away from the device 14 through the ends 30 of the electrical contacts 22, e.g., to an underlying substrate or board (not shown), and to the extended portion 28 of the heat spreader 24. Alternatively, depending upon the heat distribution within the package 12 and system 10, which may change during operation of the device 14, heat may be conducted from the device 14 to the heat spreader 24, and through the extended portions 28, to an underlying substrate. Preferably, the heat spreader 24 in the system 10 of the invention reduces junction-to-case thermal resistance (θJC), particularly at the top and sides of the package 12, and also reduces junction-to-board thermal resistance (θJB) due to the influence of the one or more extended portions 28 of the heat spreader 24 adapted for providing an enhanced thermal path at the board. Thus, junction-to-air thermal resistance (θJA) is preferably reduced due to improvements in both JC and JB heat egress paths.

Many alternative embodiments of the invention are possible. In an alternative embodiment of a package system 10 according to the invention, as shown in FIG. 2, for example, an external heat sink 32 may be attached to the heat spreader 24, using adhesive 25, whereby heat egress from the heat spreader 24 to the surrounding air may be increased. A substrate, such as a PCB 34, also conducts heat, preferably through contact with the ends 30 of the leads 22 and the coplanar extended portions 28 of the heat spreader 24. It should be appreciated that, due to the characteristic of thermal conduction from hot-to-cold, junction-to-case thermal resistance (θJC) improvements in turn benefit junction-to-board resistance (θJB), and vice versa.

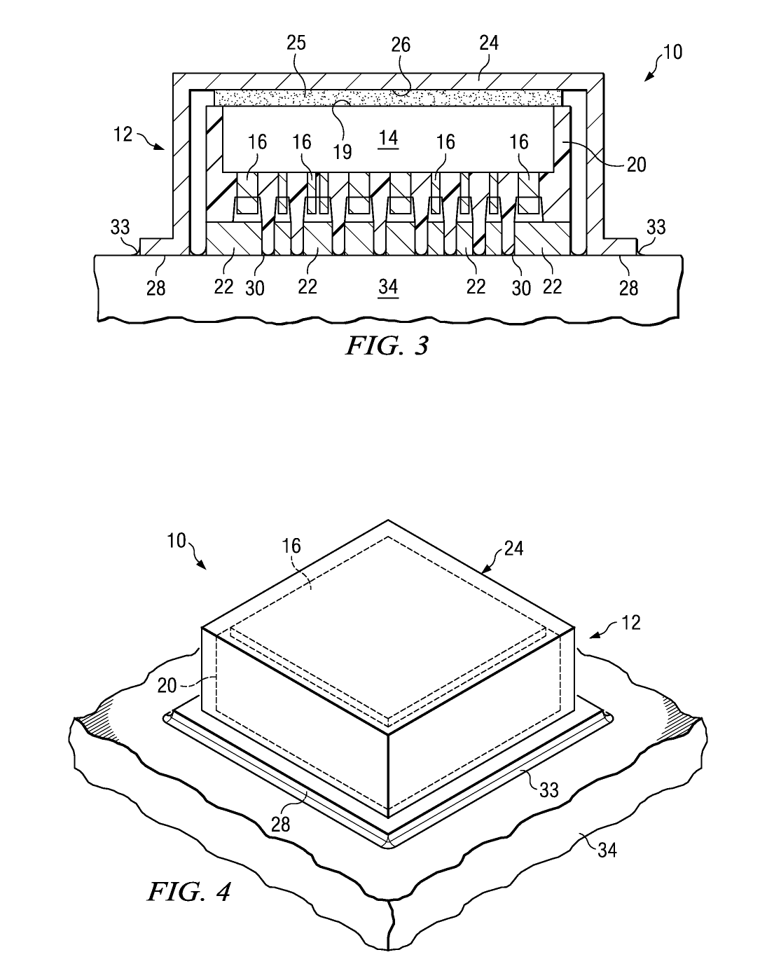

Another alternative embodiment of a system 10 according to the invention is depicted in FIG. 3, in which a device 14 is in direct contact with a heat spreader 24, preferably via thermal compound 25 or adhesive, without the intervention of a die pad as shown in the embodiments illustrated in FIGS. 1 and 2. The die pad may be omitted, as is sometimes the case for reducing cost and complexity, leaving the surface 19 of the device 14 exposed at the top of the package 12 for direct contact with the surface 26 of the heat spreader 24. Another alternative, as shown, is that a die pad 16 may be interposed between the device 14 and substrate 34. The package 12 of the system 10 of FIG. 3 also illustrates the use of the invention with a surface-mountable package 12, such as a flip-chip or BGA, having leadless electrical contacts 22, e.g., terminating in solder joints 30, connected to a PCB 34. As in the other embodiments described herein, the ends, in this case solder joints 30, of the electrical contacts 22 are capable of transmitting heat to the PCB 34, and the extended portions 28 of the heat spreader 24 also preferably provide enhanced thermal paths where in contact with the PCB 34, where it is preferably attached with suitable adhesive 33.

A top perspective view of a preferred embodiment of a package system 10 according to the invention is shown in FIG. 4. As can be seen in this example, the system 10 of the invention may include a package 12 completely covered by a heat spreader 24 having an extended portion 28, preferably coplanar and in contact with, and affixed with suitable adhesive 33 to the underlying PCB 34. The alternative embodiments of the invention shown and described herein my include a heat spreader 24 endowed with an extended portion 28 encircling the package 12 as shown in FIG. 4, the heat spreader being adaptable to accommodate various leadless or leaded package types. The area and configuration of the extended portion 28 of the heat spreader 24 may be adapted to particular application requirements without departure from the invention.

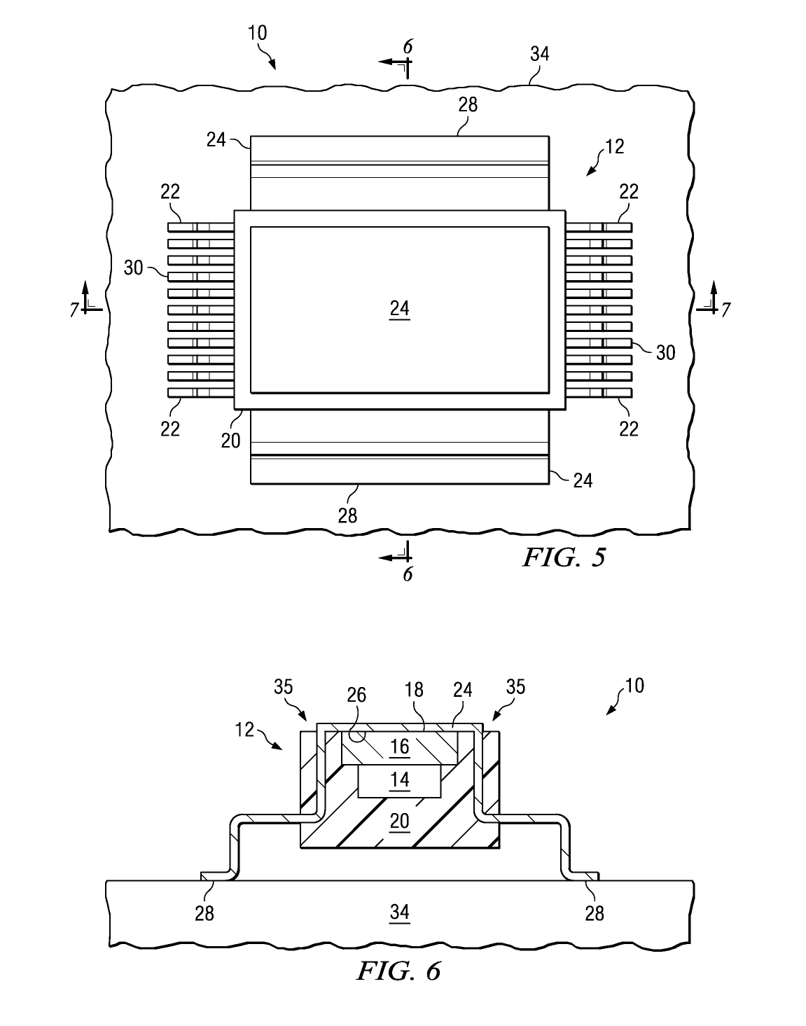

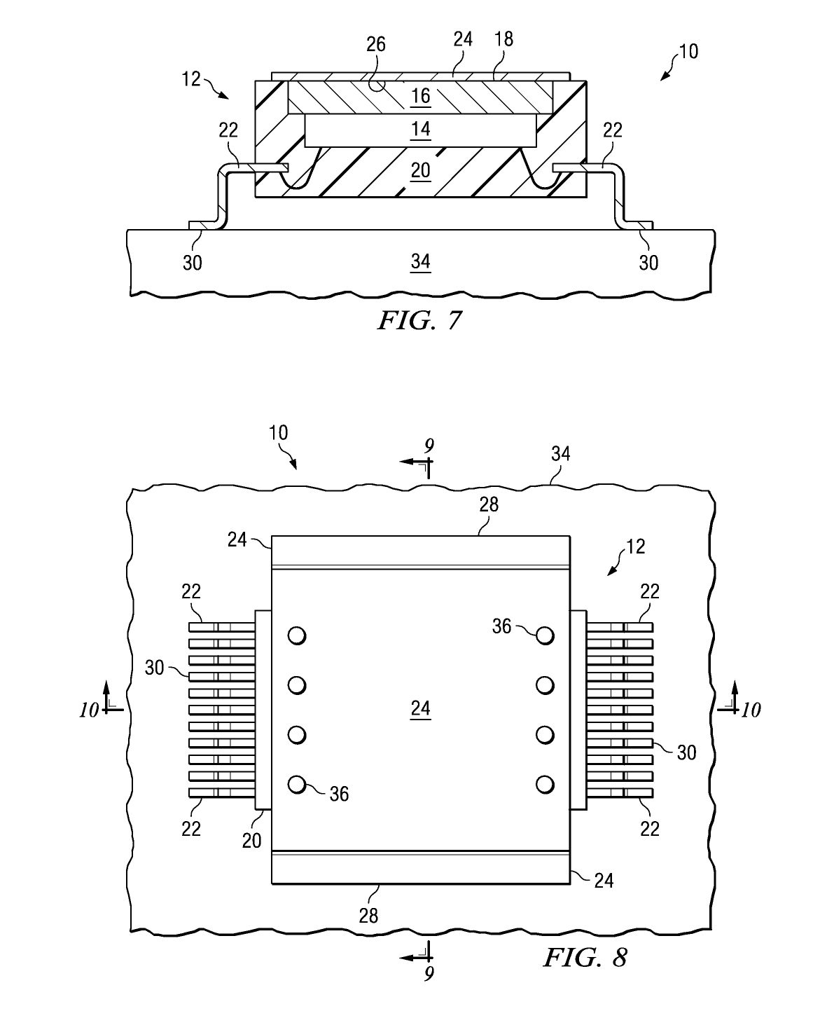

Views of another embodiment of the invention are shown in FIGS. 5, 6, and 7, in which a system 10 of the invention includes a heat spreader 24 spanning a DIP package 12. A top view is shown in FIG. 5, with section views shown in FIGS. 6 and 7 corresponding to lines 6-6 and 7-7 respectively. In this example, a heat spreader 24 is shown extending through a portion of the mold compound 20 encapsulating the package 12. The mold compound 20 and heat spreader 24 interface is preferably configured to overlap to the extent suitable for forming an interlocking joint 35. As above, the heat spreader 24 is preferably attached in contact with a surface 18 of the device 14, or intervening die pad 16 if used, and in the case of a DIP package 12 as shown, is preferably configured to have extended portions 28 situated on the sides of the DIP package 12 that are unobstructed by leads 22. In this, way the system 10 footprint may be made smaller than alternative embodiments, as shown for example in FIG. 4, in which the heat spreader may encircle a surface-mount package, DIP package, or quad package. This embodiment of the invention may be used to advantageously improve the thermal performance of DIP packages using methods which avoid the need for additional post-singulation operations to create and attach additional heat spreaders. Thermal performance of such a configuration can be further improved without departure from the invention by providing an exposed pad or external heat sink across the length of the package.

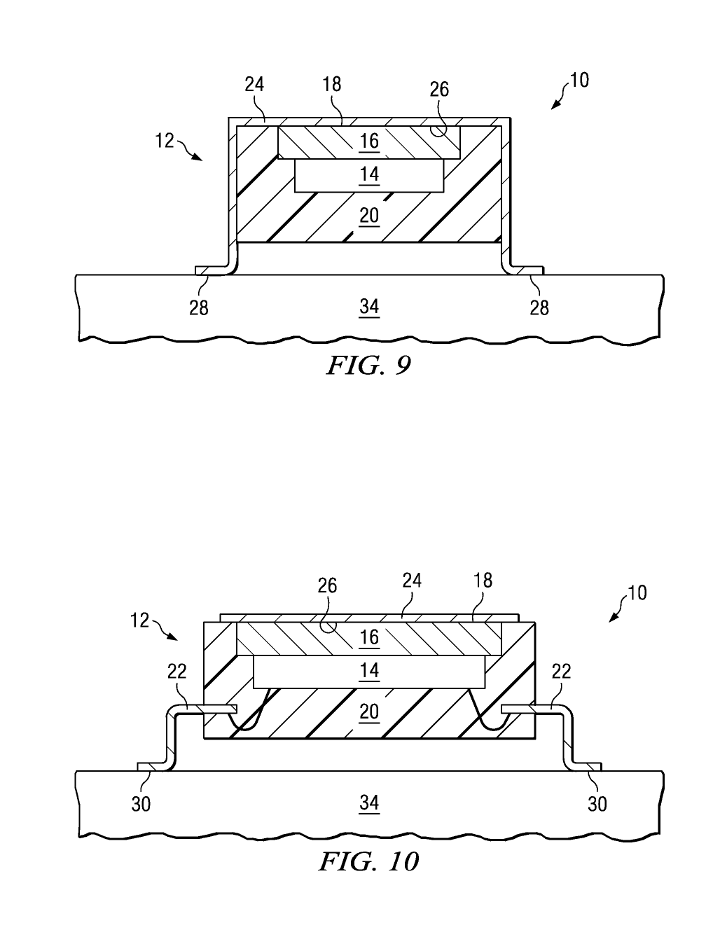

FIG. 8 is a top view of another alternative embodiment of a DIP package 12 system 10 using the invention. A DIP package 12 includes a heat spreader 24 attached over the length of a die pad 16 at the top surface 18 of the device 14. As with the other embodiments shown, the die pad 16 may be omitted. The heat spreader 24 preferably includes extended portions 28 coplanar with the ends 30 of the dual in-line leads 22. Mold lock features, such as mold compound 20 filled apertures 36 in the heat spreader 24 may be used to ensure secure attachment of the heat spreader 24 to the package 12. FIG. 9 is a side view of the system 10 of FIG. 8 cut away at line 9-9, in which it can be seen that the extended portions 28 of the heat spreader 24 preferably come into contact with the PCB 34. In the cutaway side view of FIG. 10, the system 10 of FIG. 8 is shown cut along 10-10.

Providing a heat spreader in a package system according to the invention can enhance thermal performance of pad-up packages, reducing thermal resistance to the case and board. The invention may be practiced as a post-singulation operation in conjunction with standard manufacturing techniques, permitting cost-effective implementation. For example, leads may be formed conventionally. Packages using the system of the invention may be affixed to a conventional PCB and may also use a conventional external heat sink. The invention is useful with, but not necessarily limited to packages such as QFN, BGA and flip-chip packages. In any of such configurations, the overall heat dissipation can be considerably increased. The methods and systems of the invention provide one or more advantages including but not limited to reducing the cost of increasing thermal efficiency in semiconductor package systems, increasing design flexibility for dissipating heat from a package with or without the addition of an external heat sink, further increasing design flexibility by providing systems adaptable to various package types and applications. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

I claim:

1. A semiconductor device package system comprising:
a packaged semiconductor device having operable contacts for external electrical coupling, the device having an exposed surface; and
a heat spreader affixed to the exposed device surface and extending in a configuration coplanar with the device contacts.

2. A semiconductor device package system according to claim 1 wherein the operable contacts for external electrical coupling further comprise leads.

3. A semiconductor device package system according to claim 1 wherein the operable contacts for external electrical coupling further comprise surface-mountable contact pads.

4. A semiconductor device package system according to claim 1 further comprising a die pad interposed between the exposed device surface and the heat spreader.

5. A semiconductor device package system according to claim 1 further comprising a PCB for receiving the operable contacts of the device and the coplanar portion of the heat spreader.

6. A semiconductor device package system according to claim 1 further comprising a substrate for receiving the operable contacts of the device and the coplanar portion of the heat spreader, and wherein the operable contacts further comprise solder balls.

7. A semiconductor device package system according to claim 1 further comprising an external heat sink affixed to the heat spreader.

8. A semiconductor device package system according to claim 1 further comprising an interlocking joint coupling the heat spreader and the packaged device.

9. A semiconductor device package system according to claim 1 wherein the heat spreader encircles the packaged device.

10. A method for assembling a semiconductor device package system comprising the steps of:
providing a packaged semiconductor device having operable contacts for external electrical coupling with a substrate, the device also having an exposed surface;
affixing a heat spreader to the exposed device surface, wherein the heat spreader further comprises at least one extended portion coplanar with the device contacts for contacting the substrate.

11. A method according to claim 10 further comprising the step of affixing the operable contacts of the packaged device and the extended portion of the heat spreader to a substrate.

12. A method according to claim 10 further comprising the step of affixing a heat sink to at least one surface of the heat spreader.

13. A method according to claim 10 further comprising the step of interposing a die pad between the exposed device surface and the heat spreader.

14. A method according to claim 10 whereby the heat spreader is configured for conducting heat from the device and from the substrate.

15. A method according to claim 10 whereby the heat spreader is configured for encircling the device.

16. A method according to claim 10 whereby the junction-to-board thermal resistance and junction-to-case thermal resistance are both reduced.

17. A method according to claim 10 further comprising the step of forming an interlocking joint coupling the heat spreader and the packaged device.
